(19) United States
(12) Patent Application Publication
(10) Pub. No.: US 2017/0233866 A1
(43) Pub. Date: Aug. 17, 2017

(54) Film Forming Apparatus, Film Forming Method, and Computer-Readable Storage Medium

(71) Applicant: TOKYO ELECTRON LIMITED, Tokyo (JP)

(72) Inventor: Masami OIKAWA, Iwate (JP)

(21) Appl. No.: 15/429,857

(22) Filed: Feb. 10, 2017

(30) Foreign Application Priority Data
Feb. 15, 2016 (JP) 2016-025891

(51) Int. Cl. C23C 16/44; C23C 16/52; C23C 16/455; H01L 21/02

(52) U.S. Cl. CPC C23C 16/4412; H01L 21/02532; H01L 21/0262; H01L 21/02595; C23C 16/52; C23C 16/455

(57) ABSTRACT

A film forming apparatus includes: a processing chamber receiving a substrate and performing a film forming process for forming a predetermined film; a gas supply means supplying inert gas; an exhaust means exhausting an inside of the processing chamber to adjust a pressure in the processing chamber; an impurity concentration detecting means detecting impurity concentration in the processing chamber; and a controller performing a purge process which includes supplying the inert gas into the processing chamber without exhausting the inside of the processing chamber and exhausting the inside of the processing chamber without supplying the inert gas into the processing chamber when the impurity concentration detected by the impurity concentration detecting means is equal to or more than a predetermined value, and perform the film forming process with respect to the substrate when the impurity concentration detected by the impurity concentration detecting means is less than the predetermined value.

### CROSS-REFERENCE TO RELATED APPLICATION

This application claims the benefit of Japanese Patent Application No. 2016-025891 filed on Feb. 15, 2016, in the Japan Patent Office, the disclosure of which is incorporated herein in its entirety by reference.

### TECHNICAL FIELD

The present disclosure relates to a film forming apparatus, a film forming method, and a non-transitory computer-readable storage medium.

### BACKGROUND

A conventional film forming apparatus is known, which supplies process gases to a substrate, such as a semiconductor wafer, to form a predetermined film on the substrate. If impurities, such as moisture or the like, remain on the surface of the substrate in the case of forming a predetermined film on the substrate, in some cases, desired electric characteristics may not be obtained because the impurity concentration of the predetermined film increases near the interface with the substrate.

Therefore, in the prior art, the residual impurities on the surface of the substrate are removed by cleaning the substrate before forming a predetermined film on the substrate, and, thereafter, a predetermined film is formed on the substrate within a predetermined period of time, thereby inhibiting new impurities from being adsorbed onto the surface of the substrate after the cleaning.

In addition, a device is known, which measures the amount of moisture contained in process gases by a moisture meter in a process of forming a predetermined film on the substrate by supplying the process gases, and ceases the process when the amount of moisture is detected to be improper.

However, the method of cleaning the substrate is intended to uniformly remove the residual impurities on the surface of the substrate, prior to forming the predetermined film on the substrate, but is not intended to control a cleaning condition according to the amount of adsorbed impurities on the surface of the substrate. In addition, the device using the moisture meter described above is intended to cease the process when the amount of moisture is inappropriate, which is measured by the moisture meter, but is not intended to control the process according to the amount of adsorbed impurities on the surface of the substrate.

As described above, in the related art, it is not intended to control a process condition for removing the impurities according to the amount of adsorbed impurities on the surface of the substrate.

### SUMMARY

Some embodiments of the present disclosure provide a film forming apparatus capable of controlling a process condition for removing impurities according to an amount of the impurities adsorbed onto a surface of a substrate.

According to one embodiment of the present disclosure, there is provided a film forming apparatus, including: a processing chamber configured to receive a substrate and perform a film forming process for forming a predetermined film on the substrate; a gas supply means configured to supply an inert gas into the processing chamber; an exhaust means configured to exhaust an inside of the processing chamber to adjust a pressure in the processing chamber; an impurity concentration detecting means configured to detect an impurity concentration in the processing chamber; and a controller configured to perform a purge process that includes a supply step of supplying the inert gas into the processing chamber without exhausting the inside of the processing chamber and an exhaust step of exhausting the inside of the processing chamber without supplying the inert gas into the processing chamber when the impurity concentration detected by the impurity concentration detecting means is equal to or more than a predetermined value, and perform the film forming process with respect to the substrate when the impurity concentration detected by the impurity concentration detecting means is less than the predetermined value.

According to another embodiment of the present disclosure, there is provided A film forming method, including: depressurizing an inside of a processing chamber by exhausting the inside of the processing chamber using an exhaust means after receiving a substrate in the processing chamber; detecting an impurity concentration in the depressurized processing chamber; determining whether or not the impurity concentration is equal to or more than a predetermined value; performing, at least once, a purge process that includes a supply step of supplying an inert gas into the processing chamber without exhausting the inside of the processing chamber and an exhaust step of exhausting the inside of the processing chamber without supplying the inert gas into the processing chamber before the impurity concentration becomes less than the predetermined value, when the impurity concentration is equal to or more than the predetermined value,; and performing a film forming process for forming a predetermined film on the substrate when the impurity concentration is less than a predetermined value.

According to another embodiment of the present disclosure, there is provided a non-transitory computer-readable storage medium that stores a program for executing the film forming method in the film forming apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematically vertical sectional view showing an example of a film forming apparatus of the present embodiment.

FIG. 2 is a flowchart showing an example of a film forming method of the present embodiment.

FIGS. 3A and 3B are views showing an analysis result of the impurity concentration in the film by SIMS.

### DETAILED DESCRIPTION

Hereinafter, an embodiment of the present disclosure will be described with reference to the accompanying drawings. In addition, in the present specification and drawings, a substantially identical element will bear the same reference numeral and the duplicate description thereof will be omitted.

### (Film Forming Apparatus)

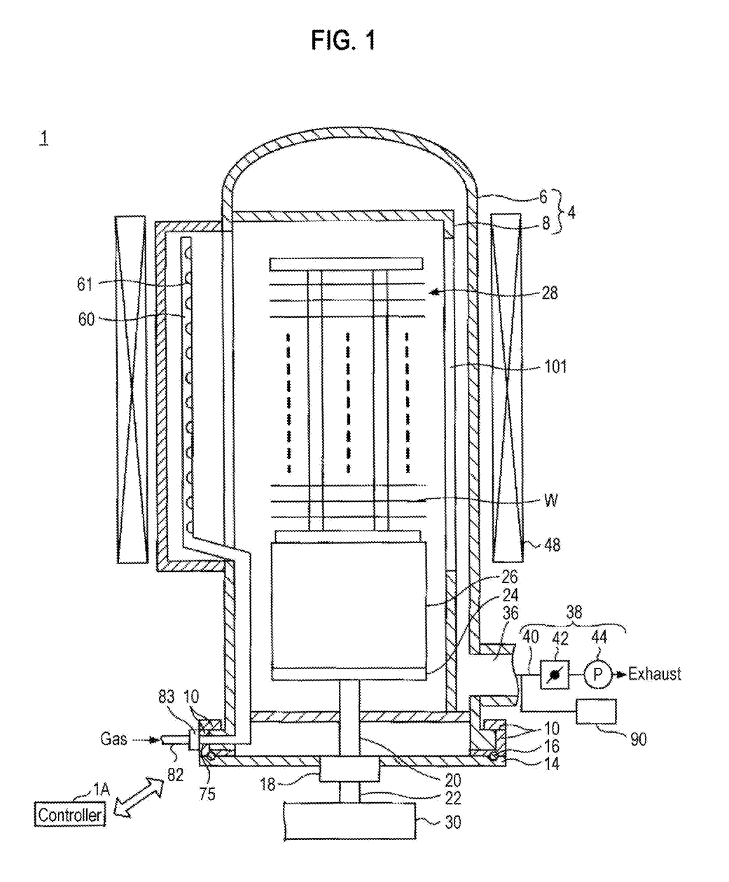

The film forming apparatus of the present embodiment will be described based on FIG. 1. FIG. 1 is a schematically vertical sectional view showing an example of a film forming apparatus of the present embodiment.

As shown in FIG. 1, a film forming apparatus 1 is a batch-type longitudinal film forming apparatus that performs a process for a plurality of semiconductor wafers (hereinafter, referred to as a “wafer W”) at one time.

The film forming apparatus 1 includes a processing vessel 4 in a substantially cylindrical shape whose longitudinal direction is a vertical direction. The processing vessel 4 has a double-cylinder structure that includes an outer cylinder 6 having a ceiling and an inner cylinder 8 that is concentrically arranged inside the outer cylinder 6 and has a ceiling. A lower end of the inner cylinder 8 has a flange that protrudes outwards and is fixed to an inner wall of the outer cylinder 6 by welding or the like. A lower end of the outer cylinder 6 has a flange that protrudes outwards, and a lower surface of the flange of the outer cylinder 6 is supported by an annular bottom flange 10 that is formed of, for example, stainless steel. The bottom flange 10 is fixed to a base plate by a fixing means such as bolts or the like.

A cap 14 formed of, for example, stainless steel in a disc shape is hermetically provided in an opening of a lower end of the bottom flange 10 by means of a seal member 16, such as an O-ring or the like. In addition, a rotary shaft 20 passes through an approximate center of the cap 14 to be rotatable in a hermetical state by, for example, a magnetic fluid seal 18. A lower end of the rotary shaft 20 is coupled to a rotation mechanism 22, and a table 24 formed of, for example, stainless steel is fixed to an upper end of the rotary shaft 20.

A heat insulation pipe 26 made of, for example, quartz is installed on the table 24. In addition, a wafer boat 28 made of, for example, quartz is mounted on the heat insulation pipe 26. The wafer boat 28 is a substrate holding tool like a shelf for holding a plurality of wafers W inside the processing vessel 4. The wafer boat 28 receives, for example, 50 to 150 sheets of wafers W at a predetermined interval (for example, in a pitch of 10 mm).

The table 24, the heat insulation pipe 26, and the wafer boat 28 are integrally loaded into or unloaded from the processing vessel 4 by means of a lifting mechanism 30, for example, a boat elevator.

A gas introduction pipe 82 is installed on a lateral side of the bottom flange 10 such that the gas introduction pipe 22 supplies process gases for a film forming process of the present embodiment to be described later or a purge gas for a purge process of the present embodiment to be described later into the processing vessel 4. A type of process gas may be selected according to a type of predetermined film that is formed on the wafer (W). For example, in the case of using chemical vapor deposition (CVD) to embed a polycrystalline silicon film (a polysilicon film) as a gate electrode on the wafer (W) where trenches or holes are formed in advance, a monosilane (SiH₄) gas and the like are thermally decomposed in atmosphere of a nitrogen (N₂) gas or a hydrogen (H₂) gas. Inert gases, such as an N₂ gas, may be used as the purge gas. In addition, while in FIG. 1, there has been described an aspect in which the process gases and the purge gas are introduced through the same gas introduction pipe 82, the present disclosure is not limited thereto. In some embodiments, an introduction pipe for introducing the purge gas may be provided separately from the gas introduction pipe 82.

The gas introduction pipe 82 is coupled to a gas introduction port 75 by a fixing means such as a connector 83 or the like. The flange of the outer cylinder 6 has a through-hole that is formed in the position corresponding to the gas introduction port 75. The horizontal part of an injector 60 is inserted into a through hole from the inside of the processing vessel 4 and the gas introduction pipe 82 and the injector 60 are connected and fixed to each other by the joint 83.

The injector 60 is a gas supply means for supplying, to the wafer (W), process gases or a purge gas that are supplied to the gas introduction port 75 through the gas introduction pipe 82. The injector 60 may be formed of, for example, quartz or may be formed of ceramics, such as silicon carbide (SiC). In addition to as quartz and ceramics, the injector 60 may be configured by using various materials with which it is difficult to contaminate the inside of the processing vessel 4.

An upper front end of the injector 60 is sealed, and a plurality of gas supply holes 61 is formed on a lateral side of the injector 60 to supply process gases in parallel with the surfaces of the plurality of wafers W received in the processing vessel 4. In other words, a plurality of gas supply holes 61 is formed at a predetermined interval in the vertical direction, and the wafers W are heat-treated while supplying process gases in the horizontal direction from the gas supply holes 61 such that a film is formed on the wafer (W). Therefore, the gas supply holes 61 are provided on the side close to the wafer (W). In addition, FIG. 1 illustrates a single gas supply pipe 82 is installed, but the number of gas introduction pipes 82 is not limited thereto, and, for example, a plurality of gas introduction pipes 82 may be installed according to the number of used gaseous species or the like.

In addition, the film forming apparatus 1 may include an activating means for activating the process gases, which are supplied from the gas supply holes 61, by means of plasma generated by a high frequency power.

A gas outlet 36 is installed in a lower portion of the outer cylinder 6, and the gas outlet 36 is coupled to an exhaust system 38 as an example of an exhaust means. The exhaust system 38 includes an exhaust passage 40 that is coupled to the gas outlet 36, and a pressure adjusting valve 42 and a vacuum pump 44 sequentially installed on the exhaust passage 40. By means of the exhaust system 38, it is possible to exhaust an inside of the processing vessel 4 while adjusting a pressure in the processing vessel 4. In addition, the pressure in the processing vessel 4 may be detected by a pressure detecting means, such as a vacuum gauge (not shown) or the like, that is installed in the film forming apparatus 1.

A heating unit 48, such as a heater, that surrounds the processing vessel 4 to heat the wafers W is provided on an outer circumferential side of the processing vessel 4.

In addition, a slit 101 is formed in the vertical direction on a side wall of the inner cylinder 8 opposite to the injector 60 via the wafer boat 28 so that gases in the inner cylinder 8 may be exhausted. That is, the process gas supplied to the wafers W from the gas supply holes 61 of the injector 60 flows from the inner cylinder 8 to a space between the inner cylinder 8 and the outer cylinder 6 through the slit 101. Then, the process gas is exhausted through the gas outlet 36 to the outside of the processing vessel 4.

A moisture meter 90 for detecting a concentration of moisture in the processing vessel 4 is installed between the processing vessel 4 and the exhaust system 38. The moisture meter 90 is an example of an impurity concentration detecting means for detecting the impurity concentration in the processing vessel 4, and, for example, a residual gas analyzer (RGA) may be used. The moisture concentration detected by the moisture meter 90 is used for the control performed by the controller 1A as described later. In addition, FIG. 1 illustrates that the moisture meter 90 is installed between the processing vessel 4 and the exhaust system 38, but s installation position of the moisture meter 90 is not limited thereto. The installation position of the moisture meter 90 may be installed in any position where the moisture concentration in the processing vessel 4 can be detected.

Further, as shown in FIG. 1, a controller 1A, such as a computer, for controlling overall operations of the apparatus is installed in the film forming apparatus 1 of the present embodiment. Furthermore, a memory of the controller 1A stores a program that allows the film forming apparatus to perform a film forming method, which will be described later, under the control of the controller 1A. The program is configured with a group of steps for performing the film forming method described later, stored in a medium, such as a hard disk, read out by a predetermined reading device onto a memory, and then installed in the controller 1A.

### <Film Forming Method>

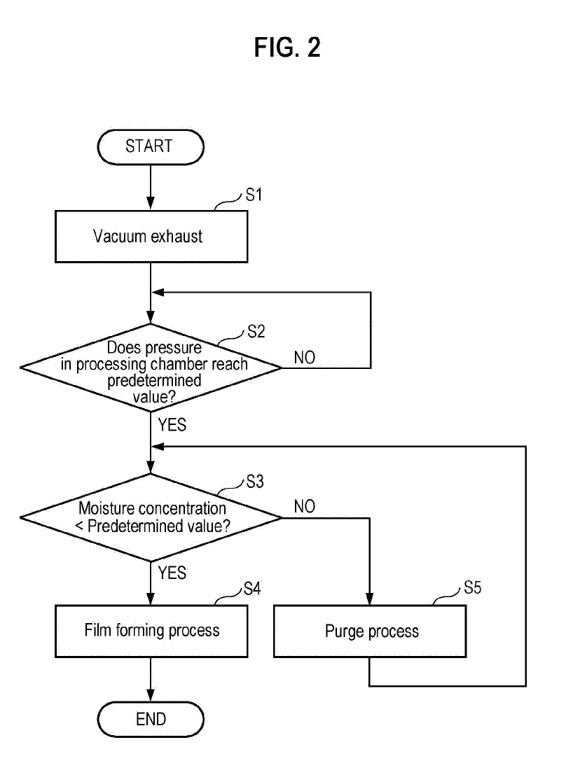

The operation of the film forming apparatus (a film forming method) of the present embodiment will be described with reference to FIG. 2. FIG. 2 is a flowchart showing an example of the film forming method of the present embodiment.

The film forming method of the present embodiment performs a purge process when the moisture concentration detected by the moisture meter 90 is equal to or more than a predetermined value, and performs a film forming process when the moisture concentration detected by the moisture meter 90 is less than the predetermined value. The purge process includes: a supply step of supplying an inert gas into the processing vessel 4 from the gas introduction pipe 82 without exhausting the inside of the processing vessel 4; and an exhaust step of exhausting the inside of the processing vessel 4 by means of the exhaust system 38 without supplying an inert gas into the processing vessel 4. The film forming process is intended to supply process gases into the processing vessel 4 from the gas introduction pipe 82, thereby forming a predetermined film on the wafer W.

Hereinafter, a method for forming a predetermined film on the wafer W by performing a film forming process with respect to the wafer W as a film forming method will be described. However, the film forming method is not limited thereto, and, for example, it may be a method in which a film forming process is performed with respect to a wafer W that has an underlying layer where a pattern, such as a trench or a hole, is formed such that a film forming material is embedded into a pattern.

First, a plurality of wafers W is transferred into the processing vessel 4 while being loaded onto the wafer boat 28. Then, the wafers are received in the processing vessel 4. Subsequently, the inside of the processing vessel 4 is exhausted by the vacuum pump 44, thereby depressurizing an inside of the processing vessel 4 (Step S1).

Subsequently, the controller 1A determines whether or not the pressure in the processing vessel 4 reaches a predetermined pressure (Step S2). The pressure in the processing vessel 4, for example, is detected by a vacuum gauge (not shown) installed in the film forming apparatus 1. The predetermined pressure may be a reaching pressure of the vacuum pump 44, when taking into consideration that it can increase a detection accuracy of the moisture concentration by the moisture meter 90. In addition, the reaching pressure means the lowest pressure that can be reached within a realistic exhaust time by the vacuum pump 44.

If the controller 1A determines that the pressure in the processing vessel 4 has reached a predetermined pressure in Step S2, the controller 1A controls the moisture meter 90 to detect the moisture concentration in the depressurized processing vessel 4, and determines whether or not the moisture concentration is less than a predetermined value (Step S3). The predetermined value may refer to the moisture concentration when the concentration of the impurity contained in a predetermined film (the impurity concentration in the film) that is formed on the wafer W in the film forming process to be described later satisfies a predetermined reference value. In addition, a relationship between the moisture concentration and the impurity concentration in the film may be determined in advance through experiments or the like.

If it is determined that the pressure in the processing vessel 4 has not reached a predetermined pressure in Step S2, Step S2 is repeated until the predetermined pressure is reached. Thus, the film forming process is not performed for the wafer W until the pressure in the processing vessel 4 reaches the predetermined pressure.

If it is determined that the moisture concentration detected by the moisture meter 90 is less than a predetermined value in Step S3, an operation of performing a film forming process is executed to form a predetermined film on the wafer W according to a predetermined film forming condition (Step S4). Then, the process is terminated.

If it is determined that the moisture concentration detected by the moisture meter 90 is equal to or more than the predetermined value in Step S3, an operation of performing a purge process is executed to purge the inside of the processing vessel 4 (Step S5). Then, the process returns to Step S3. The purge process may include: a supply step of supplying an inert gas into the processing vessel 4 from the gas introduction pipe 82 without exhausting the inside of the processing vessel 4; and an exhaust step of exhausting the inside of the processing vessel 4 by means of the exhaust system 38 without supplying the inert gas into the processing vessel 4. The supply step may be carried out, for example, for about 1 to 5 minutes, and the exhaust step may be carried out, for example, for about 1 to 5 minutes. In addition, each of the supply step and the exhaust step may be carried out once or the supply step and the exhaust step may be alternately carried out a plurality number of times. Since the impurities adsorbed onto the surface of the wafer (W) can be desorbed by performing the purge process, it is possible to reduce the impurity concentration in the vicinity of an interface with the wafer W in the predetermined film.

After the film forming process in Step S4 is completed, the wafer boat 28 on which the plurality of wafers W is loaded is unloaded from the processing vessel 4.

The film forming method of the present embodiment is implemented by the processes described above.

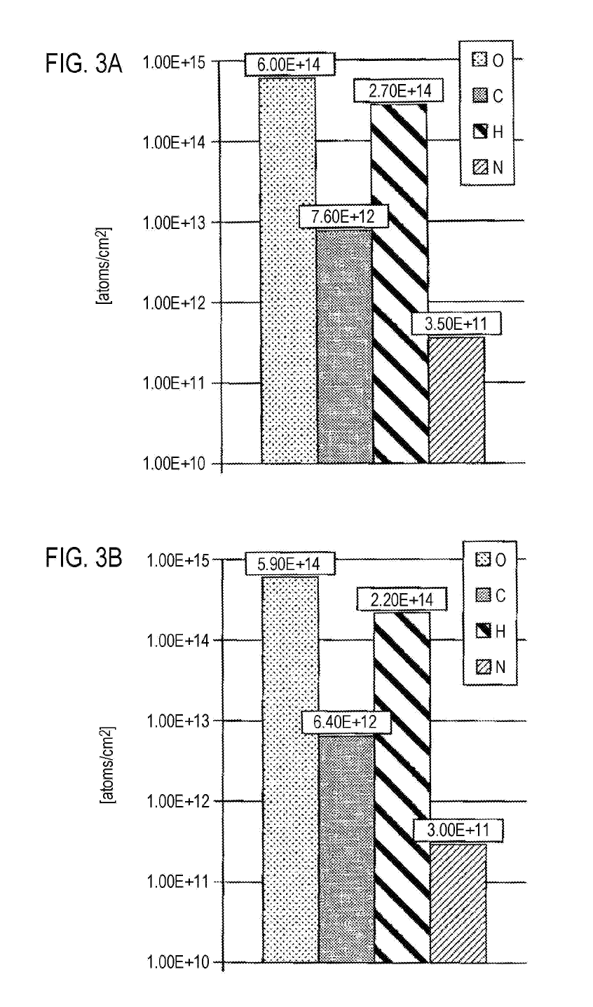

Next, the effect of the film forming method by means of the film forming device 1 of the present embodiment will be described with reference to FIGS. 3A and 3B.

FIGS. 3A and 3B illustrate an analysis result of the impurity concentration in the film by means of secondary ion mass spectrometry (SIMS). FIG. 3A shows an example in which a predetermined film was formed on the wafer W by performing a film forming process without performing a purge process. FIG. 3B shows an example in which a predetermined film was formed on the wafer (W) by performing a film forming process after performing a purge process. In addition, in the purge process, the supply step was carried out for 2.5 minutes, and then, the exhaust step was carried out for 2.5 minutes. Further, FIGS. 3A and 3B show concentrations of oxygen (O), carbon (C), hydrogen (H), and nitrogen (N) as the impurity concentration in the vicinity of the interface with the wafer W in the predetermined film formed on the wafer W.

As shown in FIG. 3A, in the case where the film forming process was performed without performing the purge process, the concentration of oxygen (O) was 6.00×10¹⁴ atoms/cm², the concentration of carbon (C) was 7.60×10¹² atoms/cm², the concentration of hydrogen (H) was 2.70×10¹⁴ atoms/cm², and the concentration of nitrogen (N) was 3.50×10¹¹ atoms/cm².

On the contrary, as shown in FIG. 3B, in the case where the film forming process was performed after performing the purge process, the concentration of oxygen (O) was 5.90×10¹⁴ atoms/cm², the concentration of carbon (C) was 6.40×10¹² atoms/cm², the concentration of hydrogen (H) was 2.20×10¹⁴ atoms/cm², and the concentration of nitrogen (N) was 3.00×10¹¹ atoms/cm².

In other words, it is possible to reduce the concentrations of oxygen (O), carbon (C), hydrogen (H), and nitrogen (N) in the vicinity of the interface with the wafer (W) in the predetermined film by performing the purge process.

As described above, the impurities adsorbed onto the surface of the wafer (W) can be desorbed by performing the purge process before forming the predetermined film on the wafer (W) by the film forming process, thereby reducing the impurity concentration in the vicinity of the interface with the wafer W in the predetermined film.

Meanwhile, there is a method for cleaning the surface of the wafer W before loading the wafers W into the processing vessel 4 of the film forming apparatus 1 in order to remove the impurities adsorbed onto the surface of the wafer W before the predetermined film is formed on the wafer W by the film forming process. However, in this method, if it takes long before the wafer W is loaded into the processing vessel 4 of the film forming apparatus 1 after the cleaning, new impurities may be adsorbed onto the surface of the cleaned wafer W.

In addition, this method is not intended to control a cleaning condition according to the amount of adsorbed impurity on the surface of the wafer W. Thus, for example, if the wafer W where more than a predetermined amount of impurities are adsorbed is loaded into the processing vessel 4 of the film forming apparatus 1, the impurities adsorbed on the wafer (W) before the film forming process may not be removed sufficiently.

Meanwhile, in the present embodiment, the purge process and the film forming process may be performed using the same film forming apparatus 1. Therefore, it is possible to form the predetermined film on the wafer W by the film forming process without allowing new impurities to be adsorbed onto the surface of the cleaned wafer W after the impurities adsorbed on the surface of the wafer W are desorbed by the purge process. As a result, it is possible to reduce the impurity concentration in the vicinity of the interface with the wafer W in the predetermined film.

In addition, in the film forming apparatus 1 of the present embodiment, if the moisture concentration detected by the moisture meter 90 is equal to or more than a predetermined value, the controller 1A makes a control to perform the purge process. Meanwhile, if the moisture concentration detected by the moisture meter 90 is less than a predetermined value, the controller 1A makes a control to perform the film forming process with respect to the wafer W without performing the purge process. According to this, it is possible to control a process condition for removing the impurities according to the amount of moisture that is adsorbed on the surface of the wafer (W). As a result, even if the wafer W on which the impurities of more than a predetermined amount are adsorbed is loaded into the processing vessel 4 of the film forming apparatus 1, the impurities adsorbed on the wafer W before the film forming process may be removed sufficiently. In addition, since there is no need to perform a purge process more than necessary, it is possible to shorten the time required for the purge process.

As described above, according to the film forming apparatus 1 of the present embodiment, the controller 1A controls whether or not the purge process is to be performed based on the moisture concentration that is detected by the moisture meter 90 before performing the film forming process. Therefore, it is possible to control a process condition for removing the impurities according to the amount of moisture adsorbed on the surface of the wafer W.

Although the film forming apparatus, the film forming method, the program, and the computer-readable storage medium have been described through the embodiments described above, the present disclosure is not limited thereto and various changes and modifications thereto may be made within the scope of the present disclosure.

Although the batch-type longitudinal film forming apparatus 1 for performing the processes with respect to the plurality of wafers W at one time is described in the embodiments, the present disclosure is not limited thereto. For example, a single-type film forming apparatus that processes the wafers (W) one by one may be used. Further, for example, a semi-batch-type apparatus may be used which revolves a plurality of wafers disposed on a rotary table in a vacuum vessel by rotating the rotary table such that the wafers pass through an area where raw material gases are supplied and an area where reaction gases which react with the raw material gases are supplied in sequence, thereby forming films on the wafers. However, if the amount of impurities adsorbed onto the surface of each wafer W prior to the film forming process is identical to each other, an absolute amount of moisture that is desorbed from the wafer W in the processing vessel 4 increases as the number of wafers W increases. In other words, the absolute amount of moisture that is desorbed from the wafer W in the batch-type film forming apparatus is greater than that of the single-type film forming apparatus. Further, the concentration of moisture is easily detected by the moisture meter 90, as the concentration of moisture increases. Therefore, since the concentration of moisture is easily detected by the moisture meter 90 in the batch-type film forming apparatus, the film forming apparatus to which the present disclosure is applied may be the batch-type film forming apparatus.

Further, the moisture meter 90 is described as an impurity detector that detects the concentration of moisture in the processing vessel 4 in the embodiments, but the present disclosure is not limited thereto and any device may be used that is able to detect the concentration of moisture in the processing vessel 4 or may be selected depending on the type of the predetermined film or the like.

According to the embodiments of the film forming apparatus, the controller executes a feedback control for controlling whether or not to perform the purge process based on the impurity concentration that is detected by the impurity concentration detecting means before performing the film forming process. Therefore, a process condition for removing the impurities may be controlled depending on the amount of adsorbed impurities on the surface of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus, comprising:
a processing chamber configured to receive a substrate and perform a film forming process for forming a predetermined film on the substrate;
a gas supply means configured to supply an inert gas into the processing chamber;
an exhaust means configured to exhaust an inside of the processing chamber to adjust a pressure in the processing chamber;
an impurity concentration detecting means configured to detect an impurity concentration in the processing chamber; and
a controller configured to perform a purge process that includes a supply step of supplying the inert gas into the processing chamber without exhausting the inside of the processing chamber and an exhaust step of exhausting the inside of the processing chamber without supplying the inert gas into the processing chamber when the impurity concentration detected by the impurity concentration detecting means is equal to or more than a predetermined value, and perform the film forming process with respect to the substrate when the impurity concentration detected by the impurity concentration detecting means is less than the predetermined value.

2. The film forming apparatus according to claim 1, wherein the impurity concentration detecting means is installed between the processing chamber and the exhaust means.

3. The film forming according to claim 1, wherein the impurity concentration detecting means is a moisture gauge that detects the moisture concentration in the processing chamber.

4. The film forming apparatus according to claim 3, wherein the predetermined film is a polysilicon film.

5. The film forming apparatus according to claim 1, further comprising a pressure detecting means for detecting the pressure in the processing chamber,
wherein the controller is further configured to control the impurity concentration detecting means to detect the impurity concentration when the pressure in the processing chamber that is detected by the pressure detecting means reaches a predetermined pressure.

6. The film forming apparatus according to claim 5, wherein the predetermined pressure is a reaching pressure of the exhaust means.

7. A film forming method comprising:
depressurizing an inside of a processing chamber by exhausting the inside of the processing chamber using an exhaust means after receiving a substrate in the processing chamber;
detecting an impurity concentration in the depressurized processing chamber;
determining whether or not the impurity concentration is equal to or more than a predetermined value;
performing, at least once, a purge process that includes a supply step of supplying an inert gas into the processing chamber without exhausting the inside of the processing chamber and an exhaust step of exhausting the inside of the processing chamber without supplying the inert gas into the processing chamber before the impurity concentration becomes less than the predetermined value, when the impurity concentration is equal to or more than the predetermined value; and
performing a film forming process for forming a predetermined film on the substrate when the impurity concentration is less than a predetermined value.

8. A non-transitory computer-readable storage medium that stores a program for executing the film forming method of claim 7 in a film forming apparatus, the film forming apparatus, comprising:
a processing chamber configured to receive a substrate and perform a film forming process for forming a predetermined film on the substrate;
a gas supply means configured to supply an inert gas into the processing chamber;
an exhaust means configured to exhaust an inside of the processing chamber to adjust a pressure in the processing chamber;
an impurity concentration detecting means configured to detect an impurity concentration in the processing chamber; and
a controller configured to perform a purge process that includes a supply step of supplying the inert gas into the processing chamber without exhausting the inside of the processing chamber and an exhaust step of exhausting the inside of the processing chamber without supplying the inert gas into the processing chamber when the impurity concentration detected by the impurity concentration detecting means is equal to or more than a predetermined value, and perform the film forming process with respect to the substrate when the impurity concentration detected by the impurity concentration detecting means is less than the predetermined value.
